(19) United States
(12) Patent Application Publication
(10) Pub. No.: US 2015/0237760 A1
(43) Pub. Date: Aug. 20, 2015

(54) SERVER DEVICE

(71) Applicant: QUANTA COMPUTER INC.., Taoyuan Shien (TW)

(72) Inventors: Maw-Zan JAU, Taipei City (TW); Chao-Jung CHEN, New Taipei City (TW); Chih-Ming CHEN, Taoyuan County (TW)

(73) Assignee: QUANTA COMPUTER INC., Taoyuan Shien (TW)

(21) Appl. No.: 14/472,536

(22) Filed: Aug. 29, 2014

(30) Foreign Application Priority Data
Feb. 18, 2014 (TW) 103105311

(51) Int. Cl. H05K 7/14

(52) U.S. Cl. CPC H05K 7/1491; H05K 7/1498

(57) ABSTRACT

A server device includes a server rack having a front opening, a network switch device disposed in the server rack, a plurality of server computers stacked in the server rack, and a plurality of signal cables located at the front opening of the server rack. The network switch device includes a plurality of first I/O ports located at the front opening of the server rack. Each of the server computers includes a plurality of second I/O ports located at the front opening of the server rack. All of the signal cables electrically connect to both of the first I/O ports and the second I/O ports toolessly, and fix on the inner surface of the server rack.

### RELATED APPLICATIONS

This application claims priority to Taiwan application no. 103105311, filed, Feb. 18, 2014, the entirety of which is incorporated herein by reference.

### BACKGROUND

1. Technical Field

The present disclosure relates to a server device. More particularly, the present disclosure relates to a server device with convenient cable management.

2. Description of Related Art

Currently, a server device provided from the current server industries includes a rack and a plurality of server units received in the rack. The server units are supported by the rack, and can be slidably pulled outwards from a front end of the rack, respectively. Signal cables of the server units are respectively arranged to a rear end of the rack, and are exposed outwards from the rear end of the rack. Thus, when a supervisor needs to maintain or replace components of anyone of the server units, the supervisor has to move to the rear end of the rack, or to dismantle the rack in order to remove the signal cables from the rear end of the rack first, and pull the server unit so that the components can be removed from the server unit pulled out of the rack.

However, no matter how quick the server unit is pulled out from the rack, or the rack is dismantled, it still takes time to remove the signal cables from the rear end of the rack so as to waste unnecessary labor and time, and also exist inconvenience of the dismantlement process of the server device. Moreover, since the hot air outlets of the server units are normally disposed on the rear end of the rack, due to the health issue, the supervisor should not stay at the rear end of the rack in a long time.

Given above, how to develop a solution capable of overcoming the mentioned shortcomings for strengthening competitiveness in the market shall be a serious issue to be concerned.

### SUMMARY

One aspect of this disclosure is to provide a server device for overcoming the above-mentioned disadvantages existing in the prior art.

According to one embodiment of this disclosure, the server device includes a server rack, at least one network switch device, a plurality of server computers and a plurality of signal cables. The server rack includes at least one inner surface, an accommodation space, a front end thereof and a rear end thereof being opposite to the front end. The front end of the server rack is provided with a front opening being in communication with the accommodation space. The network switch device is disposed in the accommodation space, and the network switch device has a plurality of first input/output ports. All of the first input/output ports are located at the front opening. The server computers are stacked in the accommodation space, each of the server computers includes a plurality of second input/output ports, and all of the second input/output ports are located at the front opening. Each of the signal cables is toolessly connected with both of the first input/output ports and the second input/output ports, and is fixed on the at least one inner surface of the server rack.

In one or more embodiments of this disclosure, the signal cables are fixed on the inner surface of the server rack, and neighboring to the front opening of the server rack.

In one or more embodiments of this disclosure, the signal cables are fixed on the inner surface of the server rack abreast, and neighboring to the front opening of the server rack.

In one or more embodiments of this disclosure, the signal cables are arranged abreast to form at least one cable layer, and the server rack includes at least one line-arranging cover. The line-arranging cover covers and fixes the signal cables of the cable layer on the inner surface of the server rack.

In one or more embodiments of this disclosure, the signal cables covered by the line-arranging cover are partially exposed outwards from the line-arranging cover.

In one or more embodiments of this disclosure, the quantity of the at least one cable layer is plural, and the cable layers are stacked with each other.

In one or more embodiments of this disclosure, the inner surface of the server rack on which the signal cables are fixed is formed with a recess, and the recess receives and fixes the signal cables of the cable layer.

In one or more embodiments of this disclosure, each of the server computers includes a tray and a motherboard module. The tray is pluggably disposed in the accommodation space. The motherboard module is coupled on the tray. The second input/output ports are disposed on the motherboard module, and electrically connected to the motherboard module.

In one or more embodiments of this disclosure, the quantity of the network switch device is plural, and the network switch devices are stacked in the accommodation space, and each of the server computers connects the network switch devices in parallel via the signal cables.

Therefore, according to the design of the server device in this disclosure, before any of the server computers is maintained or surveyed, the supervisor may proceed operating, replacing or pulling out the sever computer, or even removing cables of the sever computer from the front end of the server rack which is closer to the supervisor. Because it is not necessary to moving to the rear end of the server rack or to disassemble the server rack in order to remove the cables, the time of maintenance and inspection is saved.

These and other features, aspects, and advantages of the present disclosure will become better understood with reference to the following description, accompanying drawings and appended claims.

It is to be understood that both the foregoing general description and the following detailed description are by examples, and are intended to provide further explanation of the disclosure as claimed.

### BRIEF DESCRIPTION OF THE DRAWINGS

The present disclosure will be apparent to those skilled in the art by reading the following detailed description of a preferred embodiment thereof, with reference to the attached drawings, in which:

FIG. 1 is a perspective view of a server device according to one embodiment of the disclosure;

FIG. 2 is a partial enlarged view of an area M of FIG. 1; and

FIG. 3 is a schematic view of one of the server computers of FIG. 1.

### DETAILED DESCRIPTION

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

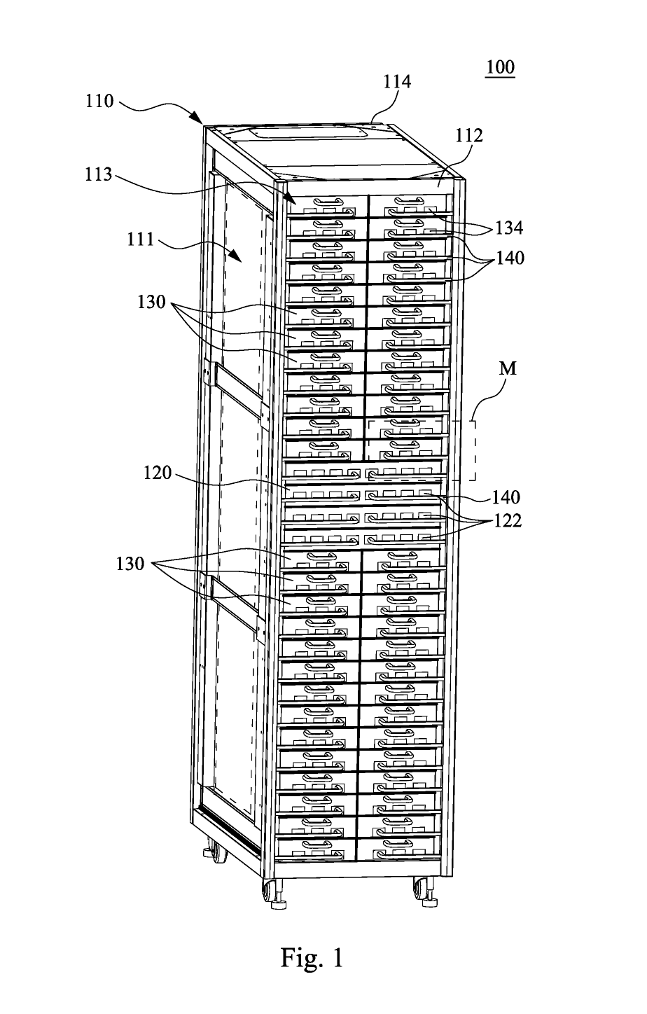

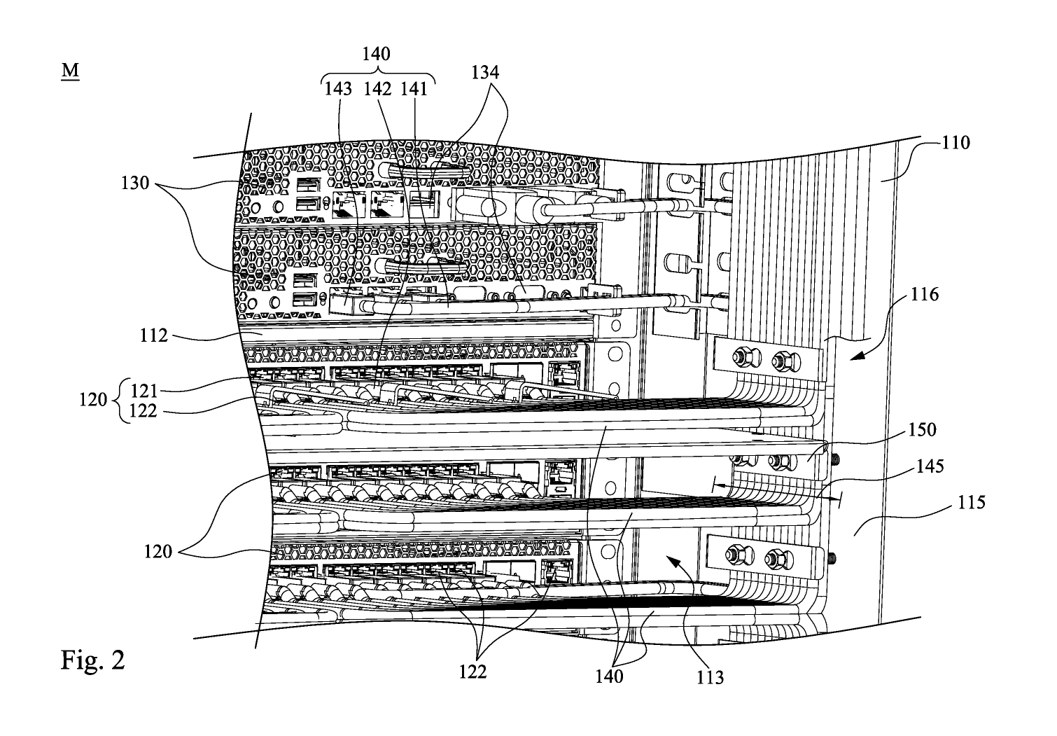

Reference is now made to FIG. 1 and FIG. 2 in which FIG. 1 is a perspective view of a server device 100 according to one embodiment of the disclosure, and FIG. 2 is a partial enlarged view of an area M of FIG. 1. According to the embodiment of this disclosure, as shown in FIG. 1 and FIG. 2, the server device 100 includes a server rack 110, at least one network switch device 120, a plurality of server computers 130 and a plurality of signal cables 140. The server rack 110 is provided with a front end 112 and a rear end 114 which are opposite to each other. The server rack 110 also is formed with an accommodation space 111 therein. The accommodation space 111 is disposed between the front end 112 and the rear end 114 of the server rack 110. The front end 112 of the server rack 110 is provided with a front opening 113, and the front opening 113 is in communication with the accommodation space 111. The server rack 110 also has plural inner surfaces 115, and the inner surfaces 115 are located at the front opening 113. The network switch device 120 is disposed in the accommodation space 111, and the network switch device 120 is provided with a plurality of first input/output ports 122. All of the first input/output ports 122 may be exposed outside the server rack 110 from the front opening 113, and neighboring to the front opening 113 of the server rack 110, or all of the first input/output ports 122 may be not exposed from the front opening 113, but located at the front opening 113. The server computers 130 are stacked in the server rack 110. Each of the server computers 130 is provided with a plurality of second input/output ports 134. All of the second input/output ports 134 may be exposed outside the server rack 110 from the front opening 113, and neighboring to the front opening 113 of the server rack 110, or all of the second input/output ports 134 may be not exposed from the front opening 113 but located at the front opening 113. The signal cables 140 respectively toolessly plug in both of the first input/output ports 122 and the second input/output ports 134, and the signal cables 140 are fixed on inner surfaces 115 of the server rack 110.

Therefore, according to the design of the server device in this disclosure, before any of the server computers 130 is maintained or surveyed, the supervisor may proceed operating, replacing or pulling out the sever computer 130, or even removing the signal cables 140 for the server computer 130 from the front opening 113 of the server rack 110 which is closer to the supervisor. Because it is not necessary to moving to the rear end 114 of the server rack 110 or to disassemble the server rack 110 in order to remove the signal cables 140, the time of maintenance and inspection is saved.

Also, in the server device 100, since the first input/output ports 122 of the network switch device 120 and the second input/output ports 134 of the server computers 130 are all located at the front opening 113, and even are all exposed outwards from the server rack 110 via the front opening 113, thus, the supervisor only needs to stay at the front end 112 of the server rack 110 where a cold-air inlet of the server device 100 is formed, for operating, replacing, plugging in, or removing the signal cables 140 from the server computer 130. Accordingly, the supervisor can work in this environment for a long time, and the health of the supervisor can be protected.

Since all of the first input/output ports 122 and the second input/output ports 134 are located at the front opening 113 of the server rack 110, or at least neighboring to the front opening 113 of the server rack 110, and no input/output ports are arranged on the rear end 114 of the server rack 110, all of the signal cables 140 are arranged on the front end 114 of the server rack 110, not on the rear end 114 of the server rack 110. Thus, the supervisor does not need to remove any cable from the rear end 114 of the server rack 110.

In this embodiment, the server computers 130 are stacked together in the accommodation space 111 of the server rack 110, and are exposed outwards from the front opening 113. Specifically, the network switch device 120 and the server computers 130 are stacked together in the accommodation space 111 of the server rack 110, for example, the network switch device 120 is in the middle of the accommodation space 111, and is sandwiched between two parts of the server computers 130. Furthermore, although the server rack 110 is made of a open-typed frame. However, in this disclosure, but not limited thereto, the server rack 110 also can be presented as a housing in other embodiments.

In this embodiment, as shown in FIG. 2, the signal cables 140 are fixed on the inner surfaces 115 of the server rack 110 where are located at, or neighboring to the front opening 113 of the server rack 110. Substantially, each of the signal cables 140 includes a cable body 141, a first connector 142 and a second connector 143. The first connector 142 and the second connector 143 are respectively disposed at two opposite ends of the cable body 141. The first connector 142 of one of the signal cables 140 plugs in, and is electrically connected to one of the first input/output ports 122. The second connector 143 of one of the signal cables 140 plugs in, and is electrically connected to one of the second input/output ports 134. The cable bodies 141 of the signal cables 140 are fixed on the inner surfaces 115 of the server rack 110 where are located at, or neighboring to the front opening 113 of the server rack 110.

Some of the signal cables 140 extends from the second input/output ports 134 of the server computers 130 to the inner surfaces 115 of the server rack 110 where are located at, or neighboring to the front opening 113 of the server rack 110, and then extends to the first input/output ports 122 of the network switch device 120 along the inner surfaces 115 of the server rack 110. Thus, the signal cables 140 can be fixed abreast on the inner surfaces 115 of the server rack 110 where are located at, or neighboring to the front opening 113 of the server rack 110. Also, for helping trimming these signal cables, one of the inner surfaces 115 of the server rack 110 on which the signal cables 140 are fixed is formed with a recess 116. The recess 116 can partially receive and fix the signal cables 140. However, the recess 116 is not necessarily needed in the disclosure. In other embodiments, the recess 116 can be omitted due to cost consideration.

In order to enhance the signal cables 140 to fix on the inner surfaces 115 of the server rack 110, in this embodiment, a part of the signal cables 140 arranged abreast to form a cable layer 145. The server rack 110 includes one or more holding covers 150. One of the line-arranging cover 150 covers the signal cables 140 of the cable layer 145, and fixes the signal cables 140 of the cable layer 145 on one of the inner surfaces 115 of the server rack 110. The holding covers 150 are arranged at intervals to cover the signal cables 140 of the cable layer 145 so that the signal cables 140 of the cable layer 145 covered by the line-arranging cover 150 are partially exposed outwards from the line-arranging cover 150.

Also, all of the signal cables 140 are arranged abreast to form plural cable layers 145. The cable layers 145 are stacked with each other, and each of the cable layers 145 is made of plural signal cables 140.

The network switch device 120 includes a mainframe 121. The mainframe 121 is disposed in the accommodation space 111, and electrically connected to at least one of the server computers 130. The first input/output ports 122 are formed on one surface of the mainframe 121 which exposed outwards from the front opening 113.

In addition, back to FIG. 1 and FIG. 2, as the quantity of the network switch device 120 is plural, the network switch devices 120 are stacked with each other in the accommodation space 111, and each of the server computers 130 connects the network switch devices in parallel via the signal cables. Moreover, the network switch devices 120 are fixedly disposed in the accommodation space 111, however, the disclosure is not limited thereto, in other embodiments, the network switch devices also are slidably disposed in the accommodation space by slide rails (not shown) prepared therein.

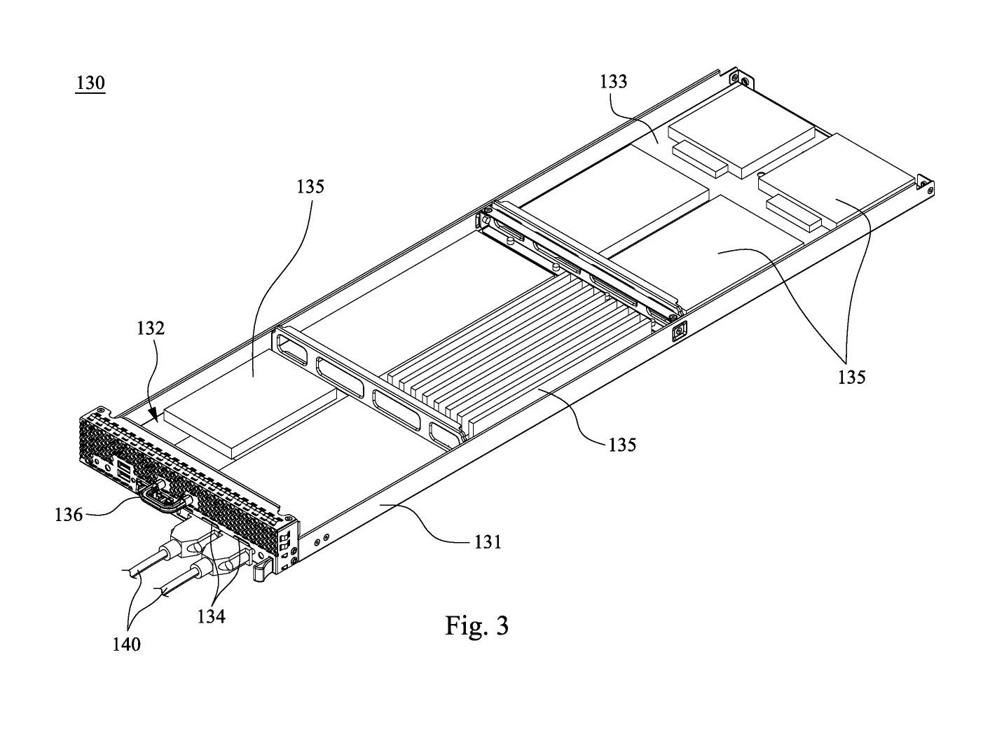

FIG. 3 is a schematic view of one of the server computers 130 of FIG. 1. As shown in FIG. 3, in the embodiment, each of the server computers 130 includes a tray 131 and a motherboard module 132. The tray 131 is pluggably disposed in the accommodation space 111 (FIG. 1), for example, the tray 131 can slide in or out the accommodation space 111 with slide rails (not shown) prepared therein. The motherboard module 132 is coupled on the tray 131, and is supported by the tray 131. The second input/output ports 134 are disposed on the motherboard module 132, electrically connected to the motherboard module 132, and exposed outwards from a front face of the tray 131.

More particularly, the motherboard module 132 further includes a motherboard 133 and plural electronic components 135. The electronic components 135 are disposed on the motherboard 133. For example, the electronic components 135 may be Center Processing Unit (CPU), Graphic Processing Unit (GPU), communication interface units, plural memory units and so on. The second input/output ports 134, for example, may be a display port (VGA), a network port or a USB port and so on. The second input/output ports 134 are fixedly disposed on one end of the motherboard 133, electrically connected to the motherboard 133, and exposed outwards from a front face of the tray 131. Also, in order to withdraw the tray 131 out of the accommodation space 111 more easily, the tray 131 has a handle 136. The handle 136 is disposed on one end of the tray 131 which is exposed outwards from the accommodation space 111 so that the supervisor may withdraw the motherboard module 132 by holding the handle 136.

Therefore, according to the design of the server device in this disclosure, before any of the server computers is maintained or surveyed, the supervisor may proceed operating, replacing or pulling out the sever computer, or even removing cables of the sever computer from the front end of the server rack which is closer to the supervisor. Because it is not necessary to moving to the rear end of the server rack or to disassemble the server rack in order to remove the cables, the time of maintenance and inspection is saved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A server device, comprising:
a server rack comprising at least one inner surface, an accommodation space, a front end thereof and a rear end thereof being opposite to the front end, wherein the front end of the server rack is provided with a front opening being in communication with the accommodation space;
at least one network switch device disposed in the accommodation space, having a plurality of first input/output ports, and all of the first input/output ports are located at the front opening;
a plurality of server computers stacked in the accommodation space, each of the server computers comprising a plurality of second input/output ports, and all of the second input/output ports are located at the front opening; and
a plurality of signal cables, each of the signal cables being toolessly connected with both of the first input/output ports and the second input/output ports and fixed on the at least one inner surface of the server rack.

2. The server device according to claim 1, wherein the signal cables are fixed on the at least one inner surface of the server rack, and neighboring to the front opening of the server rack.

3. The server device according to claim 1, wherein the signal cables are fixed on the at least one inner surface of the server rack abreast, and neighboring to the front opening of the server rack.

4. The server device according to claim 1, wherein the signal cables are arranged abreast to form at least one cable layer, and the server rack comprises at least one line-arranging cover, the line-arranging cover covers and fixes the signal cables of the cable layer on the at least one inner surface of the server rack.

5. The server device according to claim 4, wherein the signal cables covered by the line-arranging cover are partially exposed outwards from the line-arranging cover.

6. The server device according to claim 4, wherein the quantity of the at least one cable layer is plural, and the cable layers are stacked with each other.

7. The server device according to claim 4, wherein the at least one inner surface of the server rack on which the signal cables are fixed is formed with a recess, and the recess receives and fixes the signal cables of the at least one cable layer.

8. The server device according to claim 1, wherein each of the server computers comprises:
a tray pluggably disposed in the accommodation space; and
a motherboard module coupled on the tray, wherein the second input/output ports are disposed on the motherboard module, and electrically connected to the motherboard module.

9. The server device according to claim 1, wherein the quantity of the at least one network switch device is plural, and the network switch devices are stacked in the accommodation space, and each of the server computers connects the network switch devices in parallel via the signal cables.
